(19) United States
(12) Patent Application Publication
(10) Pub. No.: US 2005/0173751 A1
(43) Pub. Date: Aug. 11, 2005

(54) Semiconductor memory device

(75) Inventors: Tomoyuki Ishii, Tokyo (JP); Toshiyuki Mine, Tokyo (JP); Yoshitaka Sasago, Tokyo (JP); Taro Osabe, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/002,800

(22) Filed: Dec. 3, 2004

(30) Foreign Application Priority Data
Feb. 9, 2004 (JP) 2004-031615

(51) Int. Cl. G11C 11/34

(52) U.S. Cl. 257/314

(57) ABSTRACT

A nonvolatile semiconductor memory device that uses inversion layers formed on a surface of its semiconductor substrate as data lines, which is capable of satisfying the requirements of suppressing both characteristic variation among memory cells and bit cost. In order to achieve the above object, in the memory device, a plurality of assist gates are formed so as to be embedded in a p-type well via a silicon oxide film, respectively and silicon nanocrystal grains of about 6 nm in average diameter used for storing information are formed without being in contact with one another. Then, a plurality of word lines are formed practically in a direction vertically to the assist gates and the space between adjacent those of the plurality of word lines is set under ½ of the width (gate length) of the word lines. Consequently, the inversion layers formed at side faces of the assist gates will be used as local data lines, thereby the resistance is lowered and the writing characteristic variation among memory cells in a memory mat is suppressed.

### CLAIM OF PRIORITY

The present invention claims priority from Japanese application JP 2004-031615 filed on Feb. 9, 2004, the content of which is hereby incorporated by reference into this application.

### FIELD OF THE INVENTION

The present invention relates to a semiconductor memory device and a method for manufacturing the same and more particularly to a technique to be applied effectively for nonvolatile semiconductor memory devices that use each inversion layer formed on a semiconductor substrate as a data line.

### BACKGROUND OF THE INVENTION

Flash memories are now becoming the mainstream of semiconductor nonvolatile memories with excellent portability and used widely as data storage devices. The price of the flash memory per bit is rapidly falling year by year. The falling speed is much faster than that having been expected from the achievement of the nano-crystallization technique. This is realized by improved element structures or employed multibit storage method.

There are some methods employed for memory cell arrays of large capacity flash memories used for files. NAND type and AND type are typical flash memories realized by those methods. In the NAND type flash memory, memory cells are connected serially. In the AND type flash memory, memory cells are connected in parallel. A NAND type flash memory is disclosed, for example, by F. Arai et al., IEEE International Electron Devices Meeting pp. 775-778, 2000 (non-patent document 1) and an AND type flash memory is disclosed, for example, by T. Kobayashi et al., IEEE International Electron Devices Meeting, pp. 29-32, 2001 (non-patent document 2). On the other hand, the AND type flash memory which disposes the memory cells in parallel controls the number of electrons stored in each floating gate. This is why the AND type flash memory is considered to be suitable for multibit storage operations. In addition, the AND type flash memory employs a hot electron writing method, so that the writing is done faster.

The official gazette of JP-A No. 156275/2001 (patent document 1) discloses a nonvolatile memory technique that satisfies requirements of realizing both of a parallel memory array configuration and a smaller memory cell area. This official gazette describes how to use the inversion layer formed under each assist gate provided on a semiconductor substrate as a line. On the other hand, the official gazette of JP-A No. 169864/1995 (patent document 2) discloses a memory structure having embedded gates. The official gazette of JP-A No. 326388/2001 (patent document 3) discloses a prior art for forming a memory cell array at narrow word line pitches to realize high packing memory configuration.
[Non-patent document 1] F. Arai et al., IEEE International Electron Devices Meeting, pp. 775-778, 2000
[Non-patent document 2] T. Kobayashi et al., IEEE International Electron Devices Meeting, pp. 29-32, 2001
[Patent document 1] Official gazette of JP-A No. 156275/2001
[Patent document 2] Official gazette of JP-A No. 169864/1995
[Patent document 3] Official gazette of JP-A No. 326288/2001

As described above, because the AND type flash memory employs the hot electron writing technique, writing is done fast. In addition, because the hot electron writing employs the source-side injection, the method is considered to be suitable for writing in many memory cells simultaneously. Furthermore, because memory cells are disposed in parallel in each memory cell array in the AND type flash memory, each of those memory cells is not affected by other memory cells so easily. This is why the method realizes high multibit storage per memory cell. Such advantages are not seen in the NAND type flash memory.

However, the AND type flash memory will be confronted with the following problems. The first problem relates to the memory cell area. Because the memory array is structured so that diffusion layers are provided in parallel to one another, pitches between data lines cannot be reduced so easily in a traversal direction because of the spreading diffusion layers or presence of isolation regions. In order to solve that problem, for example, the patent document 1 (official gazette of JP-A No. 156275/2001) discloses a method for using inversion layers formed under gates that run in parallel to data lines as local data lines. According to that method, the memory can operate with a memory array in which diffusion layers to be formed by impurity injection is omitted.

Generally, the resistance of the inversion layer is higher than that of the diffusion layer formed by means of high concentration impurity injection into a semiconductor substrate. Consequently, the local data line resistance will differ among places in the subject memory cell array, so that the voltage will drop, thereby changing the potential applied to each memory cell. That causes the writing characteristic to be varied significantly among memory cells. In that connection, the longer the local data line becomes, the more the writing characteristic difference becomes remarkable. If a local data line is connected simply to a global data line via a switch to shorten the distance between them, the number of memory cells per local data line decreases, thereby the selected transistor area penalty increases. This has been a conventional problem. In addition, now that the memory structure is getting to be reduced in size more and more, the width of the gates disposed in parallel to the data lines is also required to be narrowed more. The width of lines formed with inversion layers is thus narrowed and the resistance problem will arise more remarkably.

### SUMMARY OF THE INVENTION

Under such circumstances, it is an object of the present invention to provide a technique that can satisfy the requirements of both suppression of the variation of the memory cell writing characteristic that differs among places in the subject memory cell and a lower bit cost for nonvolatile semiconductor memory devices that use inversion layers formed in a semiconductor substrate as data lines.

The above and further objects, as well as novel features of the present invention will more fully appear from the following detailed description when the same is read in conjunction with the accompanying drawings.

Hereunder, typical aspects of those to be disclosed in this application will be described.

In the semiconductor memory device of the present invention, the memory cell array is structured to have a plurality of gate lines embedded in a first conductive type semiconductor substrate and disposed in parallel to one another, a plurality of word lines practically disposed vertically to said plurality of gate lines, and charge holding means enclosed by an insulation film between a main surface of the semiconductor substrate and each of the plurality of word lines. Second conductive type inversion layers formed electrically with the plurality of gate lines on a surface of the semiconductor substrate are used as respective lines for the connection between plural memory cells.

Next, the effects of the present invention obtained by typical those of the aspects disposed in this application will be described briefly.

In the nonvolatile semiconductor memory device that uses inversion layers formed on a surface of a semiconductor substrate as data lines, the present invention can satisfy the requirements of both suppression of the writing characteristic variation among memory cells and reduction of the bit cost.

### BRIEF DESCRIPTION OF THE DRAWINGS

FIG. 1 is a schematic top view of major portions of a semiconductor substrate of a memory cell array provided in a semiconductor memory device in an embodiment of the present invention;

FIG. 2 is a cross sectional view of the semiconductor substrate at an A-B line (cross sectional direction of assist gates) shown in FIG. 1;

FIG. 3 is a cross sectional view of the semiconductor substrate at a C-D line (cross sectional direction of word lines) shown in FIG. 1;

FIG. 4 is an equalization circuit of the memory cell array in the semiconductor memory device in an embodiment of the present invention;

FIG. 5 is a cross sectional view of major portions of the semiconductor substrate in a cross sectional direction of assist gates for describing the concentration of an impurity in each region of a memory array of the semiconductor memory device in an embodiment of the present invention;

FIG. 6 is a schematic top view of major portions of the semiconductor substrate for describing the layout of a contact portion with respect to the word lines of a memory cell array of the semiconductor memory device in an embodiment of the present invention;

FIG. 7 is a cross sectional view of major portions of the semiconductor substrate for describing a contact structure with respect to the word lines of the memory cell array of the semiconductor memory device in an embodiment of the present invention;

FIG. 8 is a cross sectional view of major portions of the semiconductor substrate in a cross sectional direction of assist gates for describing a read operation from the memory cell array of the semiconductor memory device in an embodiment of the present invention;

FIG. 9 is a schematic top view of major portions of a memory mat for describing how to manufacture the semiconductor memory device in an embodiment of the present invention;

FIG. 10 is another schematic top view of major portions of the memory mat for describing how to manufacture the semiconductor memory device in an embodiment of the present invention;

FIG. 11 is still another schematic top view of major portions of the memory mat for describing how to manufacture the semiconductor memory device in an embodiment of the present invention;

FIG. 12 is still another schematic top view of major portions of the memory mat for describing how to manufacture the semiconductor memory device in an embodiment of the present invention;

FIG. 13 is still another schematic top view of major portions of the memory mat for describing how to manufacture the semiconductor memory device in an embodiment of the present invention;

FIG. 14 is still another schematic top view of major portions of the memory mat for describing how to manufacture the semiconductor memory device in an embodiment of the present invention;

FIG. 15A is a cross sectional view of major portions of the memory mat in a cross sectional direction of assist gates for describing how to manufacture the semiconductor memory device in an embodiment of the present invention;

FIG. 15B is a cross sectional view of major portions of the memory mat in a cross sectional direction of word lines for describing how to manufacture the semiconductor memory device in an embodiment of the present invention;

FIG. 16A is a cross sectional view of major portions of the memory mat in a cross sectional direction of assist gates for describing how to manufacture the semiconductor memory device in an embodiment of the present invention;

FIG. 16B is a cross sectional view of major portions of the memory mat in a cross sectional direction of word lines for describing how to manufacture the semiconductor memory device in an embodiment of the present invention;

FIG. 17A is a cross sectional view of major portions of the memory mat in a cross sectional direction of assist gates for describing how to manufacture the semiconductor memory device in an embodiment of the present invention;

FIG. 17B is a cross sectional view of major portions of the memory mat in a cross sectional direction of word lines for describing how to manufacture the semiconductor memory device in an embodiment of the present invention;

FIG. 18A is a cross sectional view of major portions of the memory mat in a cross sectional direction of assist gates for describing how to manufacture the semiconductor memory device in an embodiment of the present invention;

FIG. 18B is a cross sectional view of major portions of the memory mat in a cross sectional direction of word lines for describing how to manufacture the semiconductor memory device in an embodiment of the present invention;

FIG. 19A is another cross sectional view of major portions of the memory mat in a cross sectional direction of assist gates for describing how to manufacture the semiconductor memory device in an embodiment of the present invention;

FIG. 19B is still another cross sectional view of major portions of the memory mat in a cross sectional direction of word lines for describing how to manufacture the semiconductor memory device in an embodiment of the present invention;

FIG. 20A is still another cross sectional view of major portions of the memory mat in a cross sectional direction of assist gates for describing how to manufacture the semiconductor memory device in an embodiment of the present invention;

FIG. 20B is still another cross sectional view of major portions of the memory mat in a cross sectional direction of word lines for describing how to manufacture the semiconductor memory device in an embodiment of the present invention;

FIG. 21A is still another cross sectional view of major portions of the memory mat in a cross sectional direction of assist gates for describing how to manufacture the semiconductor memory device in an embodiment of the present invention;

FIG. 21B is still another cross sectional view of major portions of the memory mat in a cross sectional direction of word lines for describing how to manufacture the semiconductor memory device in an embodiment of the present invention;

FIG. 22A is still another cross sectional view of major portions of the memory mat in a cross sectional direction of assist gates for describing how to manufacture the semiconductor memory device in an embodiment of the present invention;

FIG. 22B is still another cross sectional view of major portions of the memory mat in a cross sectional direction of word lines for describing how to manufacture the semiconductor memory device in an embodiment of the present invention;

FIG. 23A is still another cross sectional view of major portions of the memory mat in a cross sectional direction of assist gates for describing how to manufacture the semiconductor memory device in an embodiment of the present invention;

FIG. 23B is still another cross sectional view of major portions of the memory mat in a cross sectional direction of word lines for describing how to manufacture the semiconductor memory device in an embodiment of the present invention;

FIG. 24A is still another cross sectional view of major portions of the memory mat in a cross sectional direction of assist gates for describing how to manufacture the semiconductor memory device in an embodiment of the present invention;

FIG. 24B is still another cross sectional view of major portions of the memory mat in a cross sectional direction of word lines for describing how to manufacture the semiconductor memory device in an embodiment of the present invention;

FIG. 25 is a cross sectional view of major portions of a semiconductor substrate in a cross sectional direction of assist gates of a memory cell array of a semiconductor memory device in another embodiment of the present invention;

FIG. 26 is another cross sectional view of major portions of the semiconductor substrate in a cross sectional direction of assist gates of the memory cell array of the semiconductor memory device in still another embodiment of the present invention;

FIG. 27 is still another cross sectional view of major portions of the semiconductor substrate in a cross sectional direction of assist gates of the memory cell array of the semiconductor memory device in still another embodiment of the present invention;

FIG. 28 is still another cross sectional view of major portions of the semiconductor substrate in a cross sectional direction of word lines of the memory cell array of the semiconductor memory device in still another embodiment of the present invention;

FIG. 29 is still another cross sectional view of major portions of the semiconductor substrate in a cross sectional direction of assist gates of the memory cell array of the semiconductor memory device in still another embodiment of the present invention; and

FIG. 30 is still another cross sectional view of major portions of the semiconductor substrate in a cross sectional direction of assist gates of the memory cell array of the semiconductor memory device in still another embodiment of the present invention.

### DETAILED DESCRIPTION OF THE PREFERRED EMBODIMENTS

Hereunder, the preferred embodiments of the present invention will be described with reference to the accompanying drawings. In those drawings, the same reference numerals/symbols will be used for the same parts to avoid redundant description.

### First Embodiment

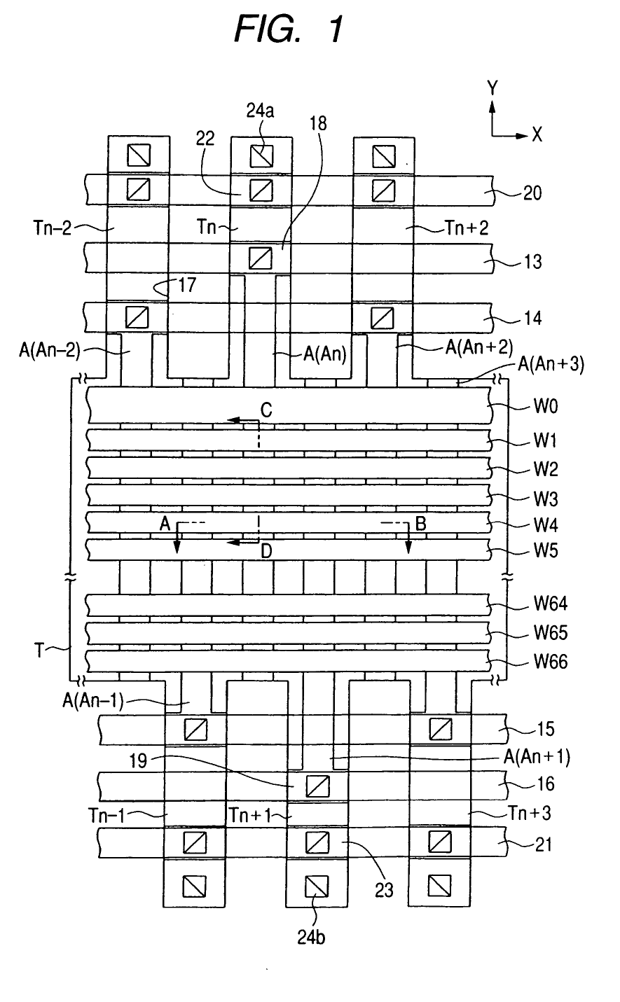

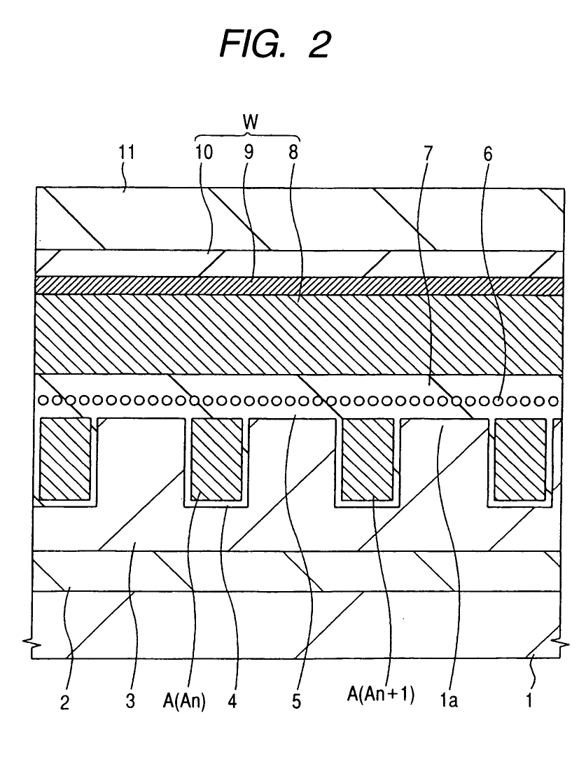

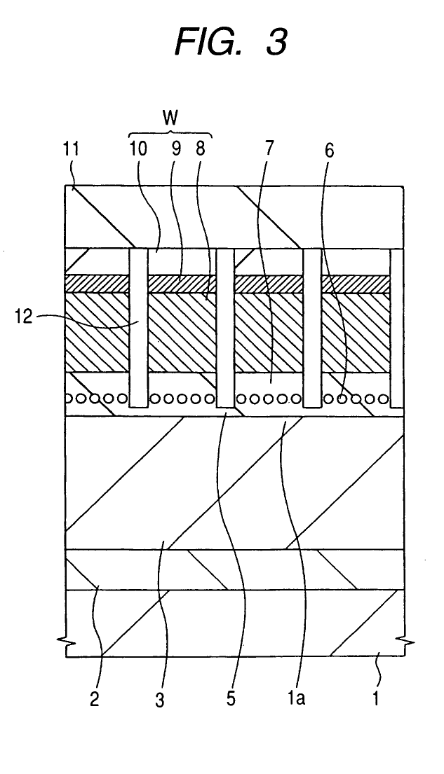

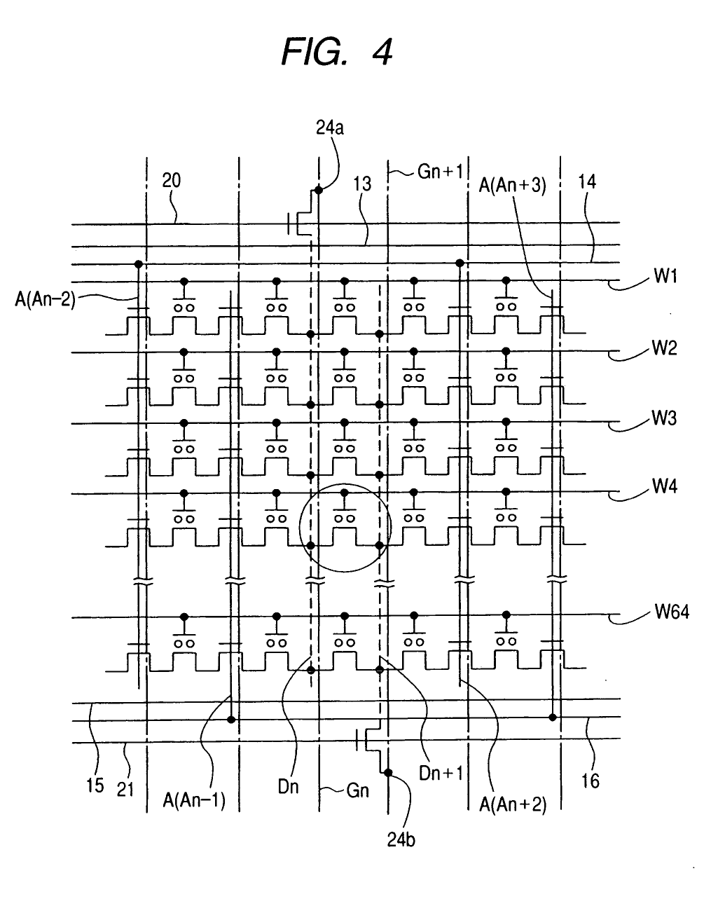

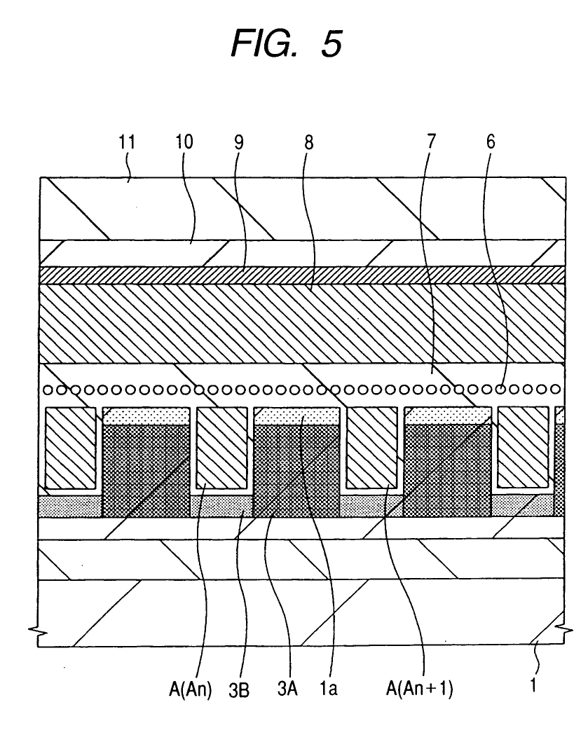

FIG. 1 shows a schematic top view of major portions of a semiconductor substrate for describing a memory cell array of a flash memory in this first embodiment of the present invention. FIG. 2 shows a cross sectional view of the semiconductor substrate at an A-B line (cross sectional direction of word lines) shown in FIG. 1. FIG. 3 is a cross sectional view of the semiconductor substrate at a C-D line (cross sectional direction of word lines) shown in FIG. 1. FIG. 4 is an equalization circuit diagram of the memory cell array. FIG. 5 shows a cross sectional view of the semiconductor substrate at the A-B line (cross sectional direction of assist gates) shown in FIG. 1 for describing the impurity concentration in each region of the memory cell array of the flash memory. In those drawings, metallic lines, etc. are omitted unless otherwise they are indispensable for description.

In the semiconductor substrate (hereinafter, to be simply referred to as the substrate) 1 constructed of p-type single crystal silicon is formed an n-type well 2. Inside the n-type well 2, a p-type well 3 is formed (triton well structure). As shown in FIG. 1, the flash memory in the first embodiment has no isolation region on its memory cell array substrate 1 except for the data line taking-out portions. Usually, the flash memory has no diffusion layer (source and drain regions) that includes metal semiconductor field effect transistors (MSFET) formed by implanting a high concentration impurity.

A plurality of assist gates A (An−2, An−1, . . . , An+2, An+3) are formed in the p-type well 3 via a silicon nitride (SiO₂) film 4 of 8 nm in thickness and embedded in the well 3. Those assist gates A are constructed of, for example, an n-type polycrystalline silicon film. At the top end, the assist gates A are aligned to the height of the surface of the silicon substrate 1a. A silicon oxide film (tunnel insulation film) 5 of about 7 nm in thickness is formed on the silicon substrate surface 1a. Over the film 5 is provided silicon nanocrystal grains 6 of about 6 nm in average diameter closely to one another while they do not come in contact with one another. The flash memory in this first embodiment is structured to store information in memory cells by injecting electrons into those silicon nanocrystal grains 6. Over the nanocrystal grains 6, an interlayer insulation film 7 of about 15 nm in thickness is formed with a silicon oxide film. In the p-type well 3, an intermediate region 3A of the embedded assist gates A is higher in concentration than the surface of the silicon substrate 1a and a portion 3B around the bottom of each assist gate A (see FIG. 5). The lower portion of each assist gate A is a low concentration p-type region. If a voltage is applied to the assist gate A to form an inversion layer there, therefore, a low resistance inversion layer is formed. The high concentration intermediate region 3A of each assist gate A is effective to prevent a punch-through phenomenon to occur between inversion layers formed at both of the subject and different assist gates A.

Over the interlayer insulation film 7 are formed a plurality of word lines W (W0, W1, W2, . . . W66) that are also used as control gates. Each word line W is formed as a laminated film consisting of, from top to bottom, an n-type polycrystalline silicon film 8, a wolfram silicide (WSi) film 9, and a silicon nitride (SiN) film 10. A silicon oxide film 11 is further formed over the silicon nitride (SiN) film 10. The word lines W are extended in a direction orthogonal to the direction in which the assist gates A are extended.

The width of the word lines W is, for example, 0.1 μm and a space 12 of about 15 nm is provided between adjacent word lines W. In other words, in the conventional flash memory, the space between adjacent word lines W is almost the same as the width (gate length) of the word lines W. In the flash memory in this first embodiment, however, the space between adjacent word lines W is under ½ of the width (gate length) of the word lines W. In the case of the conventional flash memory and the technique disclosed by the official gazette of JP-A No. 326288/2001, a silicon oxide film is provided between word lines. In the case of the present invention, however, no insulation film is provided between word lines. The space is empty in structure. Because the space is empty such way, the dielectric constant is low. For example, even when the capacitance between adjacent word lines is smaller than when such an insulation film as a general silicon oxide film is provided between word lines and the distance between adjacent word lines is short, the word lines are prevented from transmission speed down while the interference between word lines is suppressed.

As shown in FIG. 1, a memory cell array is basically composed of 67 word lines W (W0, W1, W2, . . . , W66) disposed in the Y direction (basic configuration unit referred to as a memory mat hereinafter). Of those 67 word lines W, only 64 word lines W (W1 to W64) are effective. The rest three word lines W (W0, W65, and W66) located at both ends of the memory mat in the Y direction are dummy ones that do not function as word lines W. Generally, the word lines W located at both ends of a memory mat are large in size shifting in treatment processes. This is why they are not used as memory cells. The characteristic variation of the memory mat is thus suppressed.

On the other hand, assist gates A are disposed so that adjacent four assist gates A (for example, An−2, An−1, An, and An+1) in the X direction in FIG. 1 are grouped into a set repetitively and an independent voltage is applied to each set of those assist gates through control lines 13 to 16 extended in parallel to the word lines W. In other words, the same voltage is applied to the assist gates A having the same remainder obtained by dividing ‘n’ by 4 (for example, A4, A8, A12, A16, . . . ). The number of assist gates A is, for example, 16904 (A0 to A16903) including those of a management region consisting of 2048 bytes+512 bytes, as well as those of each set of the four dummy ones located at both ends of the memory mat in the Y direction.

At each of the substrates 1 located at both ends of the memory mat in the Y direction, a plurality of active regions T ( . . . , Tn−2, Tn−1, Tn, Tn+1, Tn+2, Tn+3, . . . ) are provided with an isolation groove 17 therebetween.

A memory cell array includes, for example, 512 memory mats composed as described above in the Y direction.

In the flash memory in this first embodiment, inversion layers are formed at a neighbor substrate 1 when a positive voltage is applied to a set of assist gates A to form local data lines D ( . . . , Dn, Dn+1, . . . ) connected electrically between memory cells connected to the same assist gate A. Generally, this kind of inversion layers have higher resistance than that of the diffusion layer formed by injecting an impurity in high concentration therein, so that the application voltage will differ among places in the subject memory mat when in operation. The writing characteristic thus will differ easily among memory cells.

However, the flash memory in this first embodiment can suppress such writing characteristic variation for the following two reasons. Firstly, the local lines constructed of an inversion layer, respectively are more spaced laterally. With a progress of the nanocrystal technique, the line width of the assist gates A are required to be reduced. Otherwise, the memory cell area cannot be reduced. However, if the line width of the assist gates A is reduced in the structure as disclosed by the official gazette of JP-A No. 156275/2001, the line width of local lines is also reduced, thereby the resistance rises high. On the other hand, according to the present invention, the inversion layer at each side of each assist gate A can be used as a local data line D. The resistance can thus be reduced. Secondly, the space between adjacent word lines W is reduced to ½ or less of the width (gate length) of the word lines W, so that the local data lines D are shortened more effectively than that of the conventional structure when both are formed under the same design rules and the same number of word lines W are employed. This is why the present invention is effective to suppress the variation of the writing characteristic among memory cells while the writing characteristic depends on their places in the subject memory mat.

In the p-type well of the active regions T ( . . . , Tn−2, Tn−1, Tn, Tn+1, Tn+2, Tn+3, . . . ) formed at both ends of the subject memory mat in the Y direction, a diffusion layer constructed of an n-type impurity in high concentration is provided. This high concentration n-type impurity diffusion layer is also formed under the contact formed portions 18 and 19 used for the assist gates A while they are not formed under the select gates 22 and 23 connected to the select lines 20 and 21. In other words, the high concentration n-type impurity diffusion layer is always conductive electrically under the contact formed portions 18 and 19 used for the assist gates A while they are not conductive due to the pn junctions under the select gates 22 and 23. They are MISFETs to be turned on/off when a voltage is applied to each of the select gates 22 and 23. Consequently, for example, if a voltage is applied to the object assist gate A (An) to form an inversion layer around itself to form a local data line D (Dn), this local data line D (Dn) is connected electrically to an n-type diffusion layer of an active region T (Tn), then connected to an n-type diffusion layer connected to the contact hole 24a via a select MISFET to be controlled by a selection gate 22. In this first embodiment, the gate electrode of each select MISFET is embedded. The gate electrode may also be provided on the subject 1 just like ordinary MISFETs.

As shown in FIG. 4, a global data line G is connected to each of the above local data lines D via a select MISFET. The global data line G is extended over a plurality of memory mats and a plurality of local data lines D are connected to one global data line G (hierarchical data line structure). Consequently, the data line resistance goes down and the writing characteristic variation of memory cells among their places in the memory mat is suppressed more than when local data lines D constructed of high resistance inversion layers are extended long. When writing information in a selected memory mat, the data line voltage to be applied to the memory cells is not so high. The disturbance of non-selected memory cells can thus be suppressed. In addition, because the charging/discharging capacity is also reduced, the operation speed increases while the low power consumption is realized.

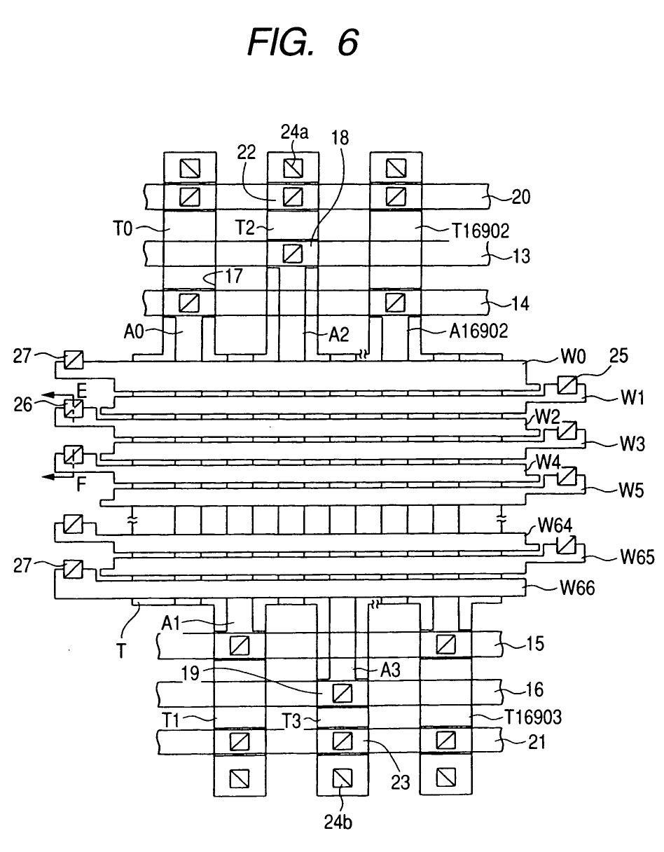

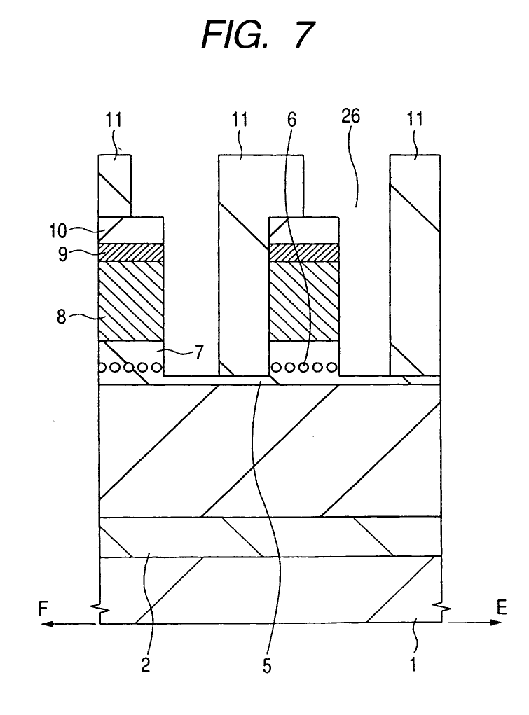

FIG. 6 shows a schematic top view of major portions of contact regions provided at both ends of a memory mat in the X direction. FIG. 7 shows a cross sectional view of a semiconductor substrate at an E-F line (cross sectional direction of word lines) shown in FIG. 6.

Just like the flash memory in this first embodiment, if the space between adjacent word lines W is reduced to ½ or less of the width (gate length) of the word lines W, some measures are required to form the contact holes to be connected to the word lines W. This is why contact holes 25 are provided at the right side of the object mat for the odd-numbered word lines W (W1, W3, W5, . . . , W65) and contact holes 26 and 27 are provided at the left side of the mat for the even-numbered word lines W (W0, W2, W4, . . . , W66). Some of those contact holes 25, 26, and 27 are disposed so as to be protruded into regions off the word lines W. As shown clearly in FIG. 6, this structure enables those contact holes to be formed not only in the top face, but also in side faces. Consequently, the contact resistance remains the same even when the contact area at the top face changes due to an alignment shift of the lithography, so that the contacts are formed stably. Because of the large contact area, the effect of the present invention remains the same even when the data line resistance goes down.

The above contact holes 25, 26, and 27 are disposed outside each active region T (in each isolation region) of the subject memory mat. Thus, even when some of the contact holes 25, 26, and 27 are disposed in a region off the word lines W, those contact holes 25 to 27 are never short-circuited with any of other conductive layers electrically.

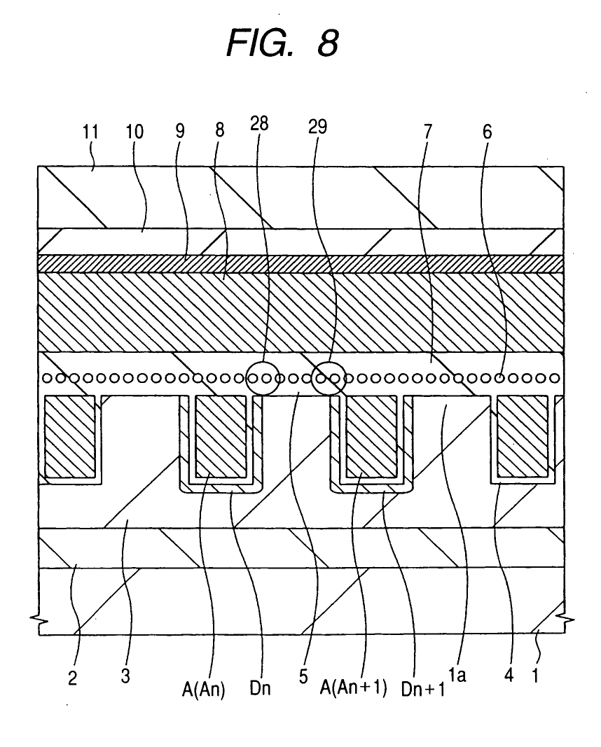

Next, a description will be made for the operation of the flash memory in the first embodiment with reference to FIG. 8. Here, the memory cells (enclosed by a circle, respectively in FIG. 4) driven by the word line W (W4), the assist gates A (An) and (An+1) are object cells in/from which information is to be written/erased in the following description. If other memory cells in the same memory mat are assumed as object ones, their operations are the same; only the selected word line W and the assist gates A come to differ from those of the above ones. In FIG. 4, the assist gates A (An and An+1) located at both sides of a write cell are omitted to simplify the description while the local data lines D (Dn and Dn+1) made respectively of an inversion layer under the assist gates A (An and An+1) are shown. The charge storage region consisting of a plurality of silicon nanocrystal grains 6 is represented by a single white circle.

In the flash memory in this first embodiment, four levels of threshold values are used for the charge storage region consisting of silicon nanocrystal grains between the assist gates A (An and An+1) to store 2-bit data. In that connection, the assist gates A (An−1 and An+2) adjacent to the assist gates A (An and An+1) function as isolation regions. As described above, four assist gates are grouped into one set and connected to one another in the set. If information is written in/read from the memory cells between assist gates A (An and An+1), therefore, information is also written in/read from the memory cells numbered so as to be separated by a multiple of 4 from those (An and An+1) like (An+4 and An+5) at the same time.

At first, a write operation will be described. In this first embodiment, both ends 28 and 29 of the charge storage region constructed of silicon nanocrystal grains 6 between adjacent assist gates A (An and An+1) are used to store 2-bit information. It is assumed here that information is written in a memory cell located closely to the assist gate A (An). A voltage (2 V, for example) enough to form an inversion layer is applied to the assist gate A (An) close to one end 28 of the charge storage region of the object memory cell and a higher voltage (7 V, for example) is applied to another assist gate A (An+1). Similarly, a low voltage (0 V, for example) insufficient to form an inversion layer is applied to the assist gates A (An−1 and An+2) adjacent to the assist gates A (An and An+1) to make electrical element isolation.

When an inversion layer is formed, an n-type diffusion layer and the local data lines D (Dn and Dn+1) are connected to each other electrically and a voltage is applied to the local data lines D (Dn and Dn+1) from the global data lines G (Gn and Gn+1) via the contact holes 24a and 24b connected to a diffusion layer. More concretely, those global data lines G (Gn and Gn+1) are set at a predetermined voltage to select a control line (select line 16/21) of the select MISFET. When 0 is to be written, both ends are set at Vsw (0 V, for example). When 1 is to be written, the local data line D (Dn) is set at Vsw (0 V, for example) and the local data line D (Dn+1) is set at a predetermined voltage Vdw (4 V, for example), respectively.

If a write pulse is applied to a word line W (W4) that is a control gate at a predetermined high voltage Vww3 (14 V, for example) for a certain time (5 μs, for example), an inversion layer is formed on the surface 1a of the silicon substrate under the word line W (W4) and electrical field concentration occurs at the interface with the local data line D (Dn) under the assist gate A (An), thereby hot electrons are generated there. The generated hot electrons are transferred to an electrical field vertical to the substrate 1 by the word line W (W4), then injected into the object memory cell. At that connection, the resistance of the local data line D (Dn) under the other assist gate A (An) rises, so that the current flowing between the local data lines D (Dn and Dn+1) does not become so large. This is why the current does not become so large even when information is written in many memory cells simultaneously, so that parallel writing in many memory cells is enabled even with the current driving performance of a limited boosting circuit. The method is thus considered to be suitable for files in/from which a great number of bits are inputted/outputted at a time. Such a hot electron injection method is referred to as a source-side injection method. Particularly, in the memory device structure of the present invention, electrons are accelerated by an electrical field of a word line W, electrons are injected in the object at high efficiency or at high speed, so that information is written fast.

When 0 is to be written, no potential difference occurs between the local data lines D (Dn and Dn+1), so that no electron is generated and no charge injection is done. No information writing is done at that time if non-selected word lines W are fixed at a sufficiently low voltage (0 V, for example) so that no electric power is supplied to the channels of the memory cells driven by non-selected word lines W.

While the other local data line D (Dn) is fixed at a high potential Vdw when in the writing, it is also possible to turn off the switch to a power line to drive the local data line D (Dn) into the floating state after precharging the data line D with a high potential, then apply a write pulse to the object word line W. If a fixed voltage is used to drive the local data line D (Dn), the resistance of the local data lines constructed of an inversion layer, respectively rises, so that the write current will be varied. However, the precharging method can fix the charge, so that the writing characteristic variation among memory cells is suppressed. This is also the same in the following embodiments. In this embodiment, if information is written in a charge storage region around the assist gate A (An+1), it is just required to change the voltage to be applied to the assist gates A (An and An+1) and the local data lines D (Dn and Dn+1) to another.

The configuration of the semiconductor memory device in this first embodiment has its specific problem; if injected electrons spread out in a direction orthogonal to the word lines W, information will be written in adjacent memory cells, since there are adjacent word lines W around the object memory cell. The present invention solves the above problem by employing the source-side injection method that enables the hot electron generating region to be narrowed and the generated hot electron energy to be distributed evenly more than those of the drain-side injection method, thereby suppressing spreading out of generated electrons in the direction orthogonal to the word lines W (direction in parallel to the assist gates A).

Therefore, unlike the conventional floating gate type 2-bit information storing method that uses four levels of injected charge amounts, the above method that 2-bit information is stored in the charge storage regions at both ends offers advantages that there is no need to control the charge injecting amount accurately, thereby the verification is simplified and the writing is speeded up. In addition, a difference between the minimum and maximum threshold levels is small, so that the writing voltage is set low, thereby the voltage is stabilized.

After that, reading is done to verify whether or not the threshold value Vth is higher than the write level Vh. The details of the reading operation will be described later. When 1 is to be written and the threshold value Vth is not higher than the write level Vh, the local data line D (Dn+1) is set again at a predetermined voltage Vdw (4 V, for example). If the threshold value Vth is higher than the write level Vh, the local data line D (Dn+1) is set at Vsw (0 V, for example), then a write pulse is applied to the word line W (W4). After that, reading is done again to verify the result. Then, a write pulse is applied to the word line W (W4) as needed. This operation sequence is repeated until the result is satisfied.

The memory array configured in this first embodiment uses adjacent memory cells for electrical isolation of elements. This is why information is written in the assist gate A of every one of four memory cells among a plurality of memory cells driven by the same word line W (W4). The write sequence is ended when the verification of all those object memory cells is completed.

Information is erased from a plurality of memory cells driven by the same word line W collectively. A positive voltage Vew (20 V, for example) that is higher than the Vww3 is applied to the object word line W. The potential in the charge storage region in which electrons are injected is low and the electric field of the interlayer insulation film 7 becomes stronger than that of the tunnel insulation film (silicon oxide film 5). As a result, electrons are moved toward the object control gate (word line W (W4)), thereby the threshold value Vth of the memory cell goes down. Information is erased from each word line W independently. Concretely, the threshold value Vth of every memory cell driven by the object word line W is set lower than the predetermined value V1, which is smaller than the write level Vh so as to erase the object information. Another method may also be used to erase the information, of course. For example, a negative voltage (−18 V, for example) may be applied to the object word line W to move the electrons toward the substrate 1. It is also possible to apply a negative voltage (−3 V, for example) to the p-type well 3, a positive voltage (3 V, for example) to the local data lines D (Dn−2, Dn−1, Dn, Dn+1, Dn+2, and Dn+3), and a negative voltage (−13 V, for example) to the word line W (W4), respectively to inject holes in the object memory cells, thereby erasing information from them. This hole injection erasing method can also be used to erase information from some memory cells selectively by selecting the inversion layers to be set at a negative voltage.

Next, a read operation will be described. It is assumed here that information is read from an end of a charge storage region located closely to the object assist gate A (An). At first, the local data line D (Dn) is precharged to a low potential Vsr (0 V, for example) and the local data line D (Dn+1) is precharged to a high potential Vdr (3.0 V, for example) through global data lines G (Gn and Gn+1), respectively.

After that, a voltage Vrw (V1<Vrw) is applied to the word line W (W4). In that connection, the Vrw is set so that the current flowing when a Vrw word voltage is applied to a memory cell of which threshold value Vth is equal to the write level Vh becomes lower enough than the current flowing when the Vrw word voltage is applied to a memory cell of which threshold value Vth is equal to V1. When the memory cell threshold value level is under V1, the local data lines D (Dn and Dn+1) are connected electrically to each other. When the threshold value level is over the write level Vh, those data lines D (Dn and Dn+1) are not connected electrically or they are high in resistance. This difference between current values is used to determine which of 0 and 1 is to be written in the object memory cell. At that time, the local data line D (Dn+1) is set at a high voltage, a pinch-off event occurs on the surface of the substrate 1 located closely to the assist gate A (An+1), so that the voltage will not affect so much the current to be applied to read information from an end 29 of a charge storage region located closely to the assist gate A (An+1). This is why information is read only from the memory cells located closely to the assist gate A (An). If information is to be read from an end 29 of a charge storage region located closely to the assist gate A (An+1), it is only required to change the voltage to be applied to the assist gates A (An and An+1) and the local data lines D (Dn and Dn+1) to another.

In this first embodiment, even-numbered word lines W (W0, W2, W4, . . . , W66) and odd-numbered word lines W (W1, W3, W5, . . . , W65) are manufactured separately, so that the line width will differ between adjacent word lines in some cases. The manufacturing processes will be described later. In order to avoid the problem, a voltage generation circuit regulator is used to change the voltage to be generated, thereby changing the operating voltage to another according to whether the object word line number is even or odd.

Furthermore, in this first embodiment, a word line voltage is used to correct the writing characteristic difference among memory cells to occur according to whether the word line number is even or odd. It is also possible to use any other means that changes the width of the pulse to be applied to each word line, as well as means that changes the voltage to be applied to each data line and/or voltage to be applied to each assist gate according to whether the object word line number is even or odd.

It is also possible to control the voltage of each assist gate A according to the position of the object memory cell in the object memory mat to suppress the variation of the voltage among the places of memory cells in the memory mat. The supply voltage is changed according to the distance between the address of the word line selected when in writing and the contact with a high-voltage-set local data line D in the memory mat. If the contact position is close, the contact is far from the low-voltage-set contact. If the contact is close in position while a write current flows under the influence of the voltage drop, therefore, both source and drain voltages of the object memory cell come to rise more than when the contact is far. Consequently, the current decreases and the word line voltage falls with reference to the source region, so that writing is apt to slow down.

It is also possible to control the voltage of the object assist gate A according to the position in the subject memory mat when in the above writing so as to suppress the variation among their positions in the memory mat. For example, when in writing, the supply voltage is changed according to the distance between the address of the selected word line and the contact with the object high-voltage-set local data line D in the memory mat. If the contact is close in position, the contact is far from the low-voltage-set contact. As a result, if the contact is close in position while a write current flows under the influence of the voltage drop, both source and drain voltages of the object memory cell come to rise more than when the contact is far. Consequently, the current flow decreases and the word line voltage falls with reference to the source region, so that writing is apt to slow down.

Consequently, a voltage to be applied to the object assist gate A corresponding to the low-voltage-set local data line D (that actually functions as a source during that operation) is set high. The source side voltage is thus suppressed from rising and the writing characteristics come to match among memory cells. Such assist gate controlling enables the voltage to be changed for each address accurately. It is also possible to divide a plurality of word lines W into groups and change the voltage for each of those groups. This will simplify the controlling.

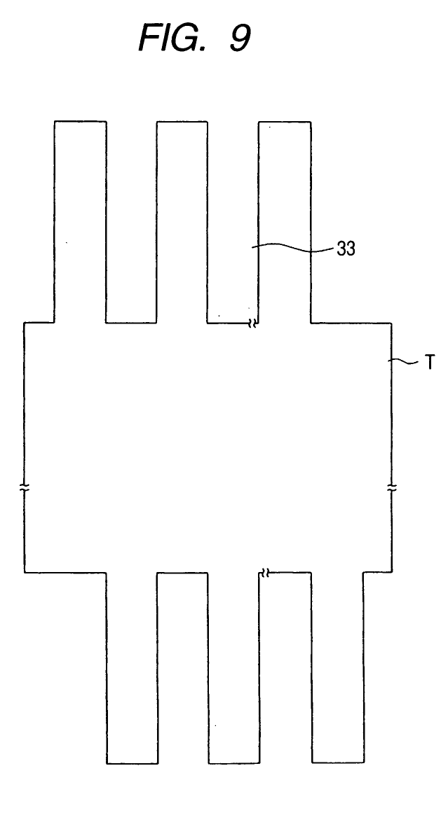

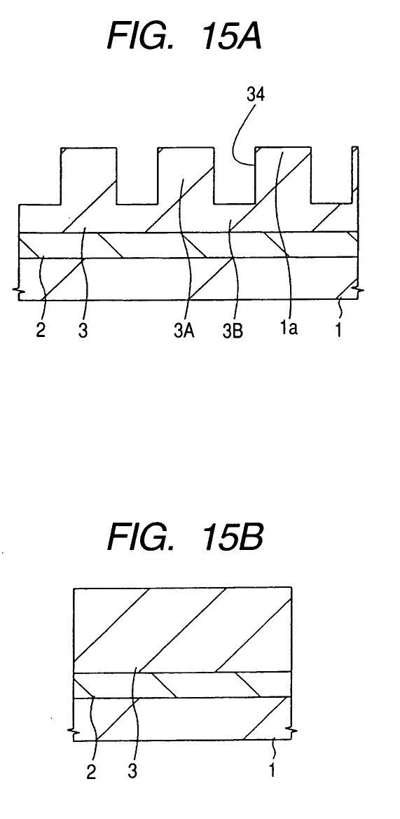

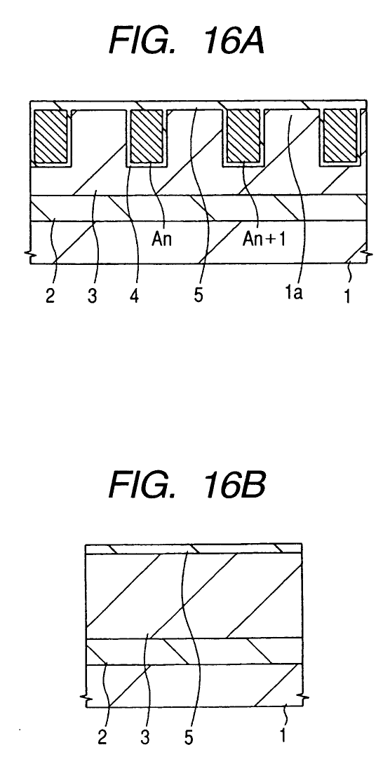

Next, a description will be made for how to manufacture the flash memory described in the first embodiment with reference to FIGS. 9 through 24. Here, a description will be made only for how to manufacture a memory cell array and the description of how to manufacture the peripheral circuit regions will be omitted. FIGS. 9 through 14 are schematic top views of major portions of the flash memory and FIGS. 15 through 24 are cross sectional views of the major portions of the same. In each cross sectional view, figure A shows the object in a cross sectional direction of assist gates and figure B shows the object in a cross sectional direction of word lines.

At first, the surface of the p-type substrate 1 is oxidized, then a silicon nitride film is deposited thereon. After that, a silicon nitride film and a silicon oxide film are deposited thereon consecutively with use of a resist pattern as a mask, then the silicon is etched to form grooves. The grooves are then filled with a silicon oxide film formed with, for example, the CVD (Chemical Vapor Deposition) method, then the surface is planarized to form isolation regions 33 and active regions T on the substrate 1, respectively. FIG. 9 shows a top view of an active region T and an isolation region 33 around the region T. As shown in FIG. 9, the isolation regions 33 are formed only in the assist gate uniting parts at the ends of the memory mat, inversion layer (local data line) contact taking-out portions, and word line contact portions; they are not formed inside the memory mat.

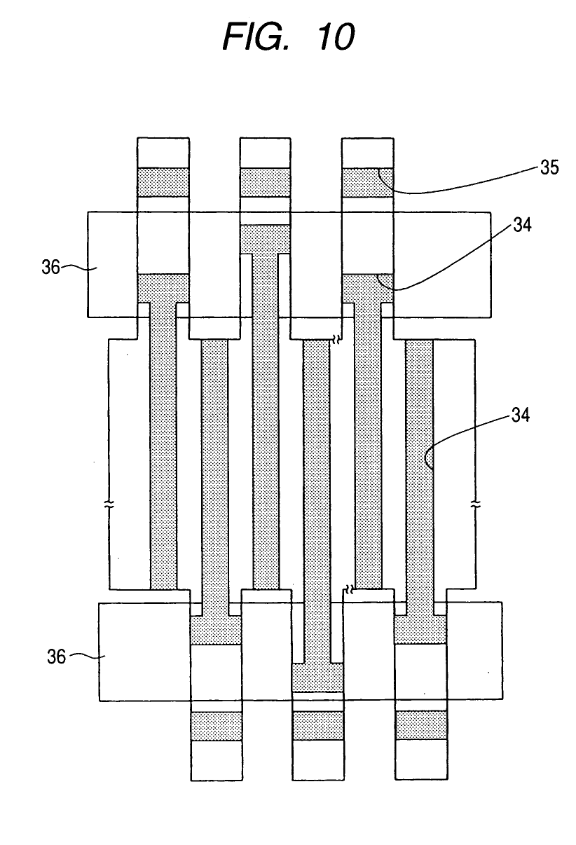

After that, impurity ions are injected into the object to form an n-type well 2 and a p-type well 3 as shown in FIG. 15. Then, the surface is etched with use of a resist pattern as a mask to form pattern grooves 34 and 35 as shown in FIG. 10. This etching should be done at a sufficiently low etching rate of the silicon oxide film so that the previously formed isolation region 33 is not scraped off. After that, n-type impurity ions are injected into the object with use of a resist hole pattern 36 as a mask. Although the n-type impurity ions are injected under the grooves 34, they are not injected under the grooves 35. Then, n-type impurity ions (arsenic (As), for example) are injected into the memory cell array region. Consequently, the region (around the bottom 3B) just under the assist gates and the silicon substrate surface 1a become p-type regions of which concentration is lower than that of the region (intermediate region 3A) between assist gates.

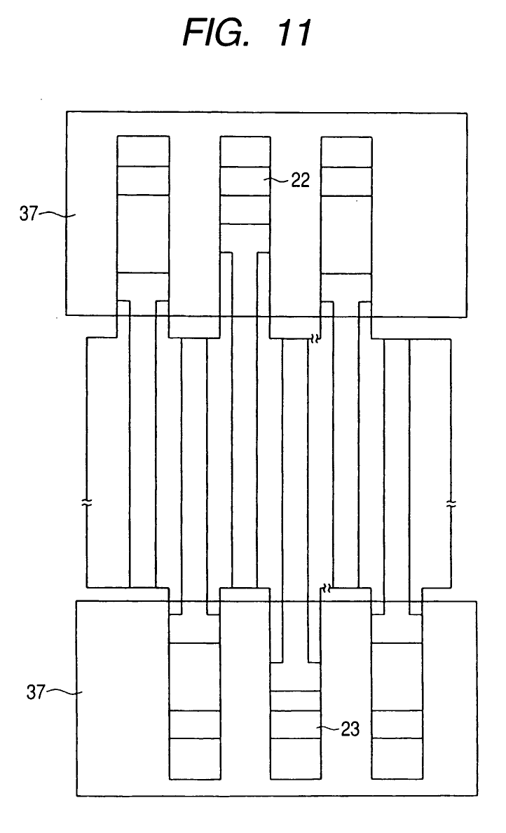

After that, the substrate 1 is oxidized by heating to form a silicon oxide film of about 8 nm in thickness on the surface of the p-type well 3, then an n-type polycrystalline silicon film is deposited thereon, then planarized to form the assist gates A and the select gates 22 and 23 for a select MISFET. The actual number of assist gates A is 16904 that includes those of the management region consisting of 2048 bytes plus 512 bytes and those of the eight dummy assist gates. In addition, a silicon oxide film is deposited on the surface with the CVD method, then an n-type impurity is injected into the silicon oxide film with use of a resist pattern 37 as shown in FIG. 11 as a mask. Thus, the select MISFET is formed.

After that, the deposited silicon oxide film is removed, then the substrate 1 is oxidized to form another silicon oxide film (tunnel insulation film) of about 7 nm in thickness on the surface of the p-type well 3.

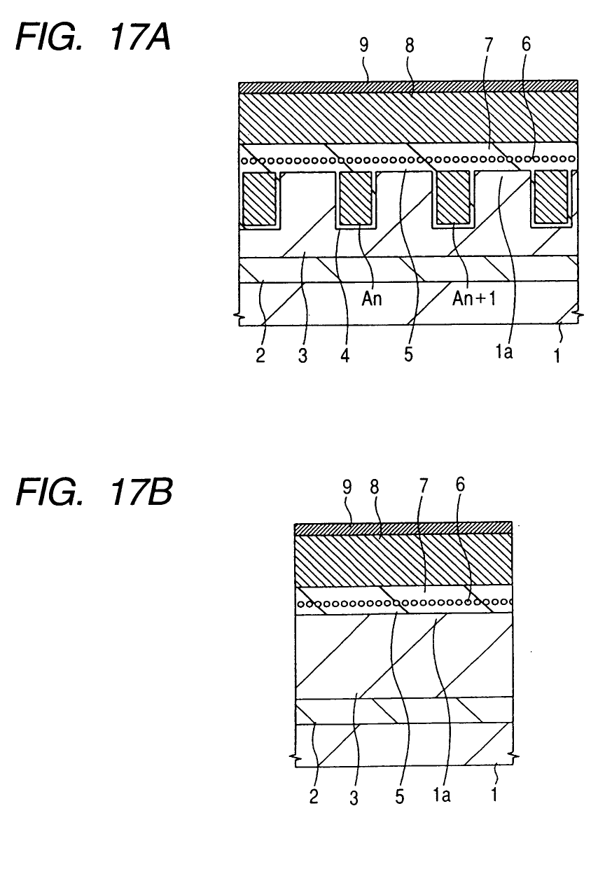

After that, silicon nanocrystal grains 6 are deposited on the surface with the CVD method as shown in FIG. 17. The surfaces of the deposited silicon nanocrystal grains 6 are then oxidized. After that, silicon nanocrystal grains 6 are deposited again on the surface to increase the concentration. Consequently, the nanocrystal grains are formed in high concentration so that they do not come into contact with one another. As a result, more electrons are accumulated under the same write conditions, thereby the accumulated information items are spaced widely and the writing characteristic of memory cells is stabilized. The concentration of the nanocrystal grains 6 in the final step is assumed to be about 10¹² per centimeter square and the average grain diameter is assumed to be about 6 nm. After that, a silicon oxide film of about 15 nm in thickness is deposited on the surface with the CVD method to form an interlayer insulation film 7, then a high concentration n-type polycrystalline silicon film 8 is deposited on the surface, then a wolfram silicide film 9 is formed thereon.

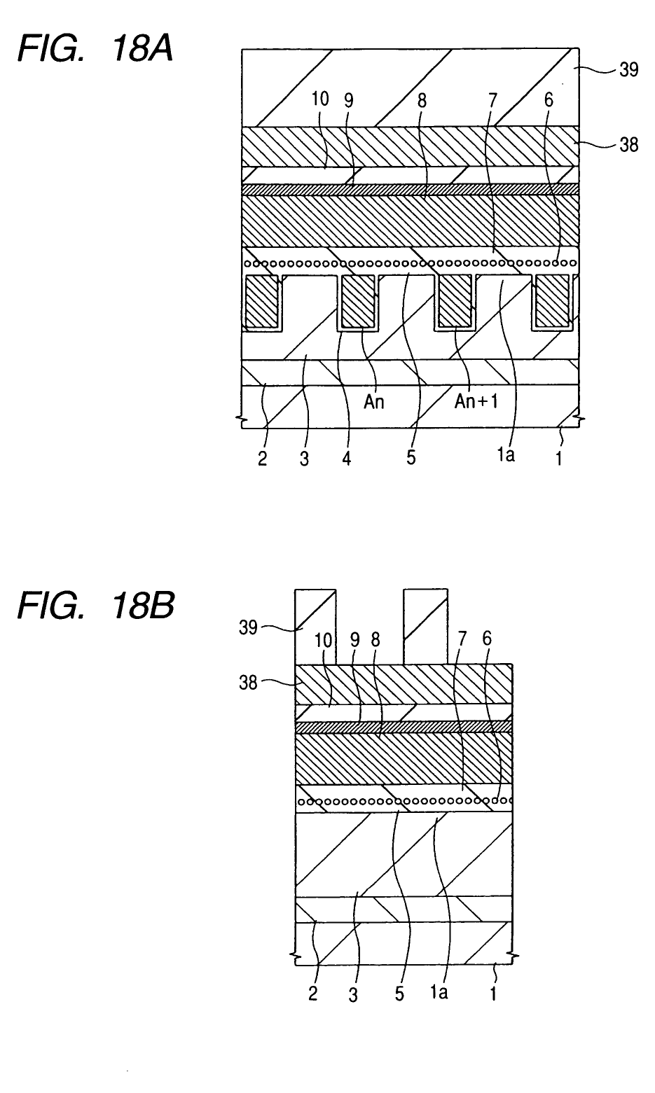

After that, a silicon nitride film 10 and a polycrystalline silicon film 38 are deposited consecutively as shown in FIG. 18. Because assist gates A are formed and embedded in the substrate 1, the surface is almost flat at that time; slight unevenness is just left over by the deposited silicon nanocrystal grains 6. The word line process margin can thus be secured easily in the subsequent process.

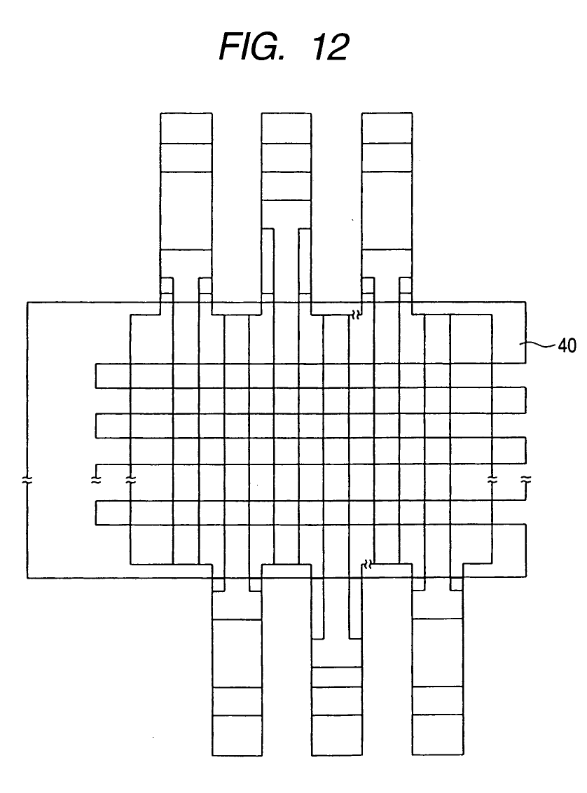

After that, a word line process is carried out. At first, the object is etched with use of a resist pattern 39 as a mask, then the polycrystalline silicon film 38 on the top face is processed into a pattern 40 shown in FIG. 12.

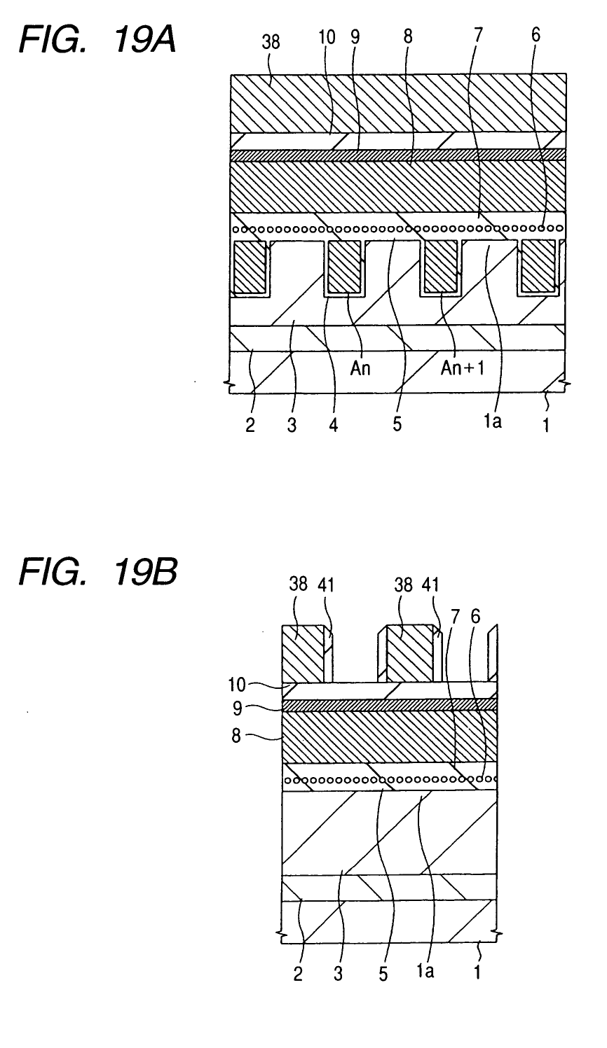

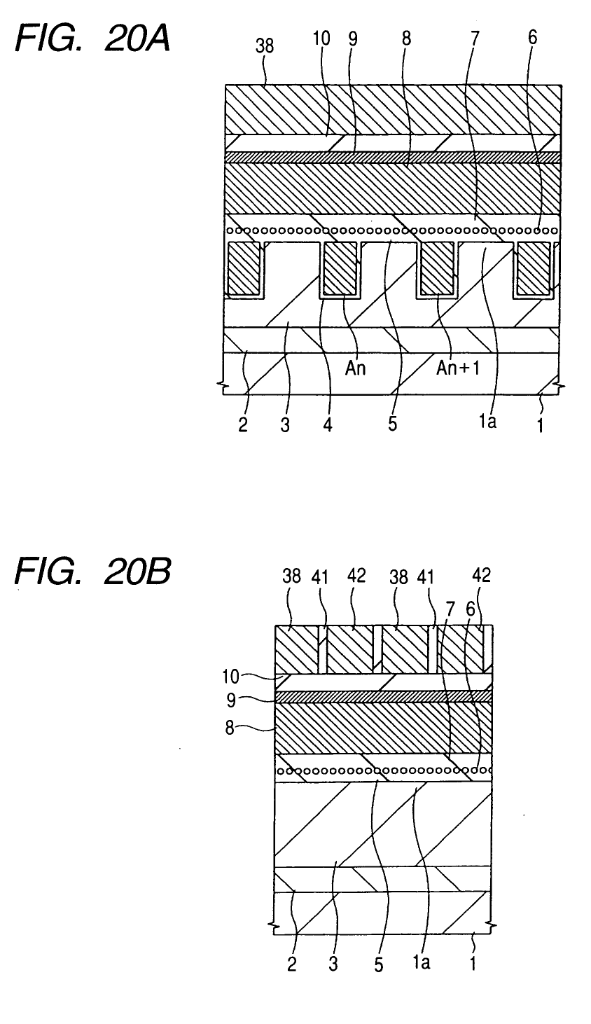

After that, a silicon oxide film 41 of about 18 nm in thickness is deposited on the surface with the CVD method as shown in FIG. 19. Then, the surface is dry-etched by 18 nm to form side walls of the polycrystalline silicon film 38. After that, a polycrystalline silicon film 42 is deposited on the surface as shown in FIG. 20, then the film surface is planarized. The surface thus will be covered completely by polycrystalline silicon films 38 and 42 separated by the silicon oxide film 41 of the side walls of the polycrystalline silicon film 38 formed previously.

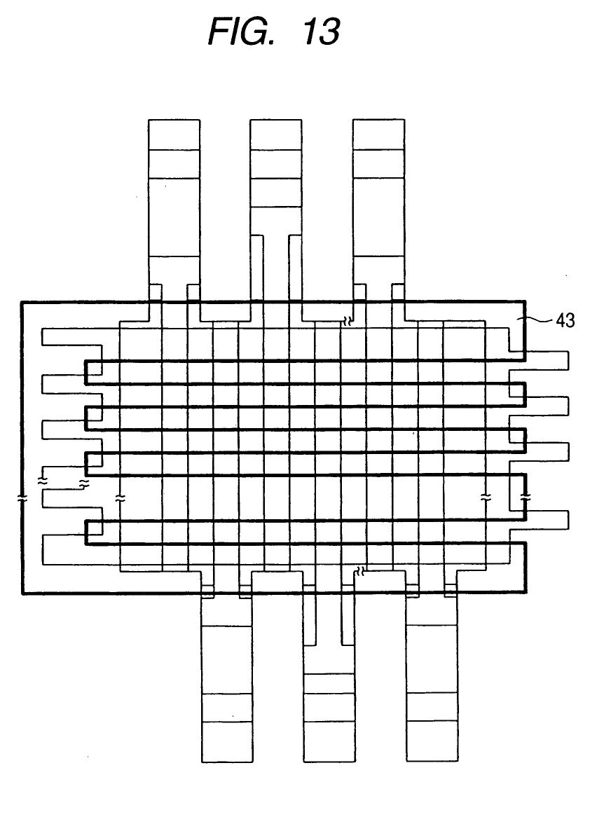

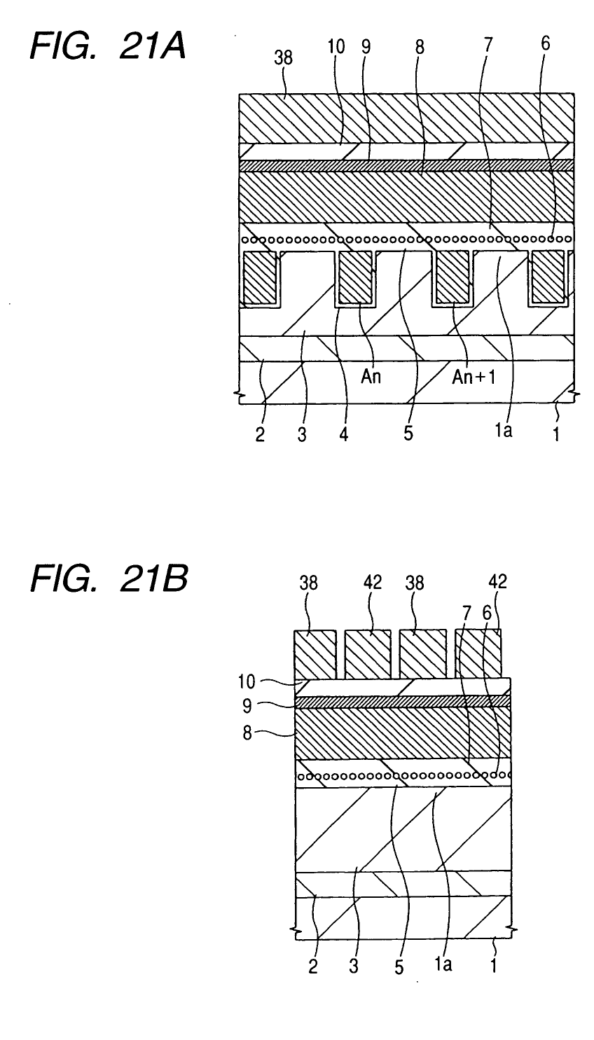

After that, the polycrystalline silicon films 38 and 42 are dry-etched with use of the resist pattern 43 shown in FIG. 13 as a mask as shown in FIG. 21. Then, the resist pattern 43 is removed and the silicon oxide film 41 is removed by wet-etching. The hard mask pattern for treating word lines is thus formed.

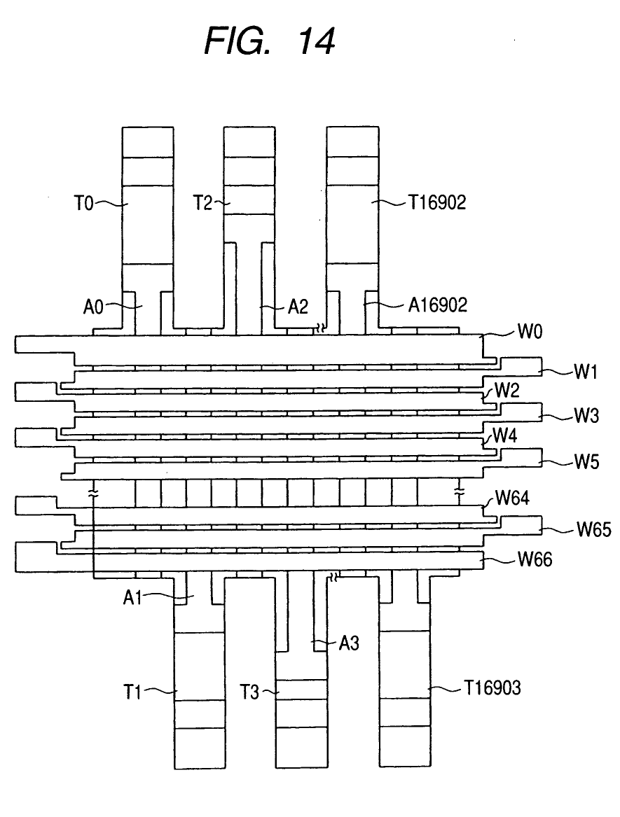

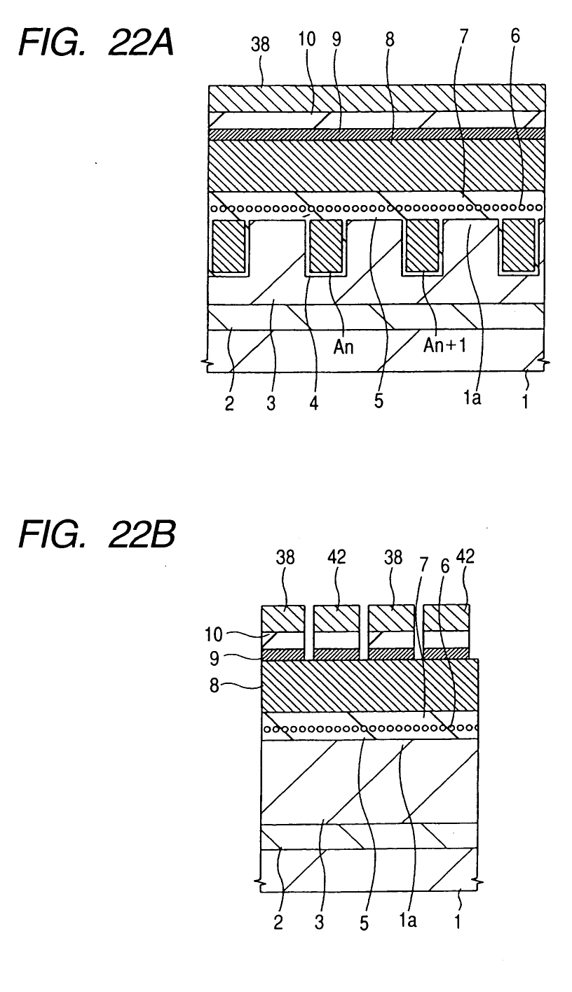

Then, as shown in FIGS. 14 and 22, the silicon nitride film 10 is dry-etched to scrape off peripheral circuits having no word line, local data line taking-out portions, as well as side wall portions where the silicon oxide film 41 has existed. After that, the wolfram silicide film 9 is dry-etched.

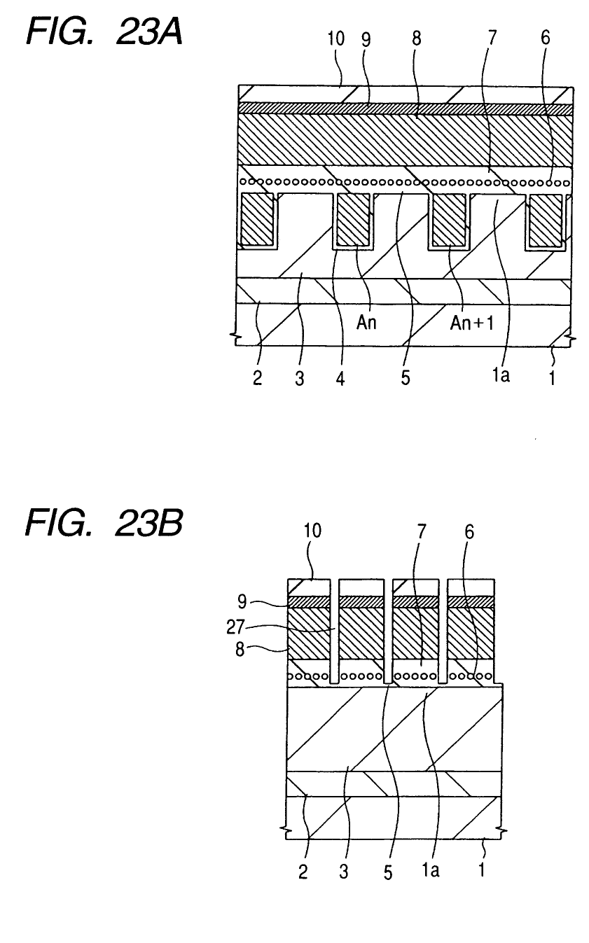

After that, as shown in FIG. 23, the polycrystalline silicon film 8 is dry-etched so that word lines W are patterned under a hard mask. In that connection, the polycrystalline silicon films 38 and 42 used as hard masks are removed from the surface. When the word lines are formed, the process may be ended. In this first embodiment, however, the silicon oxide film is further etched to remove the silicon nanocrystal grains 6 from between adjacent word lines. The accumulated charge is thus prevented from moving toward the adjacent word lines while a charge storage region that retains defective information, which exists between adjacent word lines, is excluded.

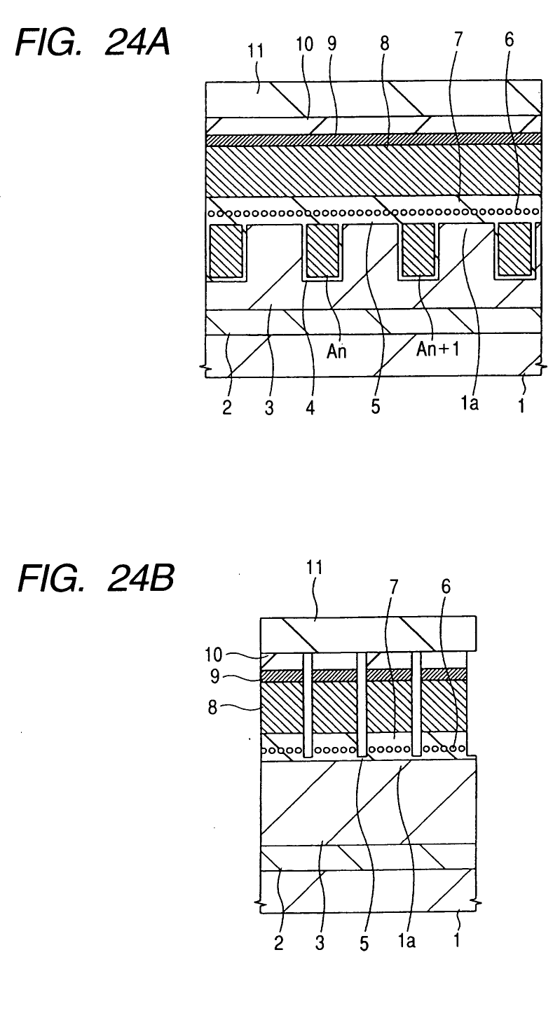

Furthermore, as shown in FIG. 24, the surface is oxidized slightly, then a silicon oxide film 11 is deposited on the top faces of the word lines W with the CVD method. At that time, a space of about 15 nm in width generated between adjacent word lines in the above process is not filled; it is left over as is, since it is too narrow to be filled.

The above word line processing method that uses dummy patterns can avoid damages of the interlayer insulation film 7 more effectively than the method disclosed in the official gazette of JP-A No. 326288/2001. In other words, according to the known processing method, the interlayer insulation film 7 that is an underlayer of the word lines W is etched when the first dummy word line pattern is formed. According to the present invention, therefore, the material of the word lines W formed so that they come in contact with the interlayer insulation film 7 is never removed. This is why the interlayer insulation film 7 is prevented from damages. Because a high voltage is applied in such a nonvolatile memory, the reliability is strictly required for the tunnel information film (silicon oxide film 5) and the interlayer insulation film 7. If this required reliability is not satisfied, the information holding characteristic and the word disturbance durability will be degraded.

After that, peripheral circuits are formed, then contact holes and lines are formed. The metallic lines in the first layer are used to form control lines 13 to 16 of the assist gates A. After that, an interlayer insulation film (not shown) is formed over the control lines 13 to 16, then global data lines G (see FIG. 4) are formed with the metallic lines in the second layer.

In the first embodiment, wells are formed as p-type ones and electrons are used as carriers. However, it is also possible to form wells as n-type ones and use holes as carriers. In that connection, the high/low voltage state is inverted from that in the first embodiment. This is the same in other embodiments.

The silicon nanocrystal grains 6 of a charge storage region may be constructed of a semiconductor material or metallic material other than silicon. They may also be constructed of an insulating material (silicon nitride film, for example) having a charge trapping function. If a charge storage region is constructed of silicon nanocrystal grains 6 just like in this first embodiment, storage nodes are insulated from one another. Thus, there is no need to process those storage nodes to be cut off at a time when in processing word lines collectively, although conventional flash memory storage nodes are cut off. This is why the same processings as those in the first embodiment may be employed in this embodiment. The same effect is obtained even when an insulating material having a charge trapping function is used for the charge storage region. It is thus possible to use an insulation film having a trapping function, such as silicon nitride, alumina, or the like for the charge storage region. If silicon nanocrystal grains 6 are used to form the charge storage region just like in the first embodiment, the charge storage region will be surrounded by an insulation material, such as a silicon oxide film having a high potential barrier and no trapping function. It is also possible to select a material that does not cause charge movement between silicon nanocrystal grains so easily to obtain a charge storage region excellent in charge holding properties. This can prevent the above described problem that charge movement occurs between silicon nanocrystal grains even when the grains are further reduced in diameter and the charge storage regions at both ends are close to each other, thereby information in adjacent memory cells will be mixed up. However, if charge movement occurs in a direction orthogonal to the direction in which word lines are extended while the space between adjacent word lines is extremely narrow just like in the first embodiment, the writing characteristics will be varied between adjacent memory cells. This problem is specific to the prior art. This first embodiment is also effective to solve the conventional problem.

### Second Embodiment

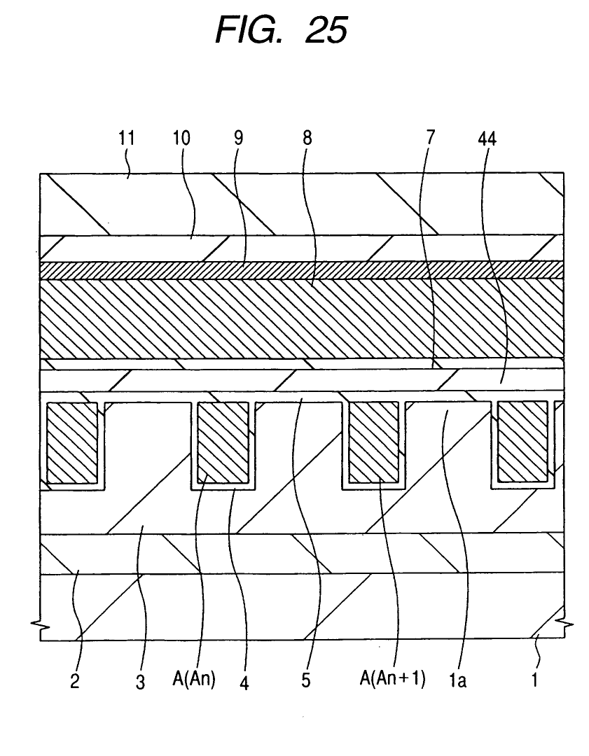

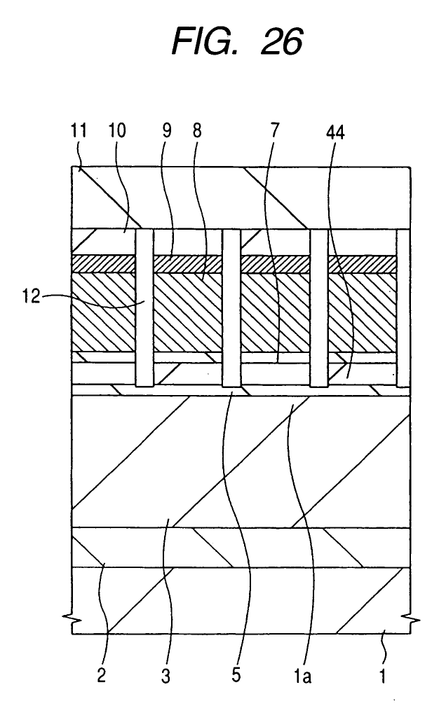

FIG. 25 shows a cross sectional view (cross sectional direction of assist gates) of major portions of a semiconductor substrate for describing a flash memory in the second embodiment of the present invention. FIG. 26 shows a cross sectional view (cross sectional direction of word lines) of the major portions in a vertical direction of the semiconductor substrate.

The memory array configuration and the operation of the flash memory in this second embodiment are the same as those in the first embodiment. In this second embodiment, each charge storage region is constructed of a silicon nitride film 44.

An insulation film having a trapping function, such as silicon nitride, alumina, or the like is formed flatly, so that the film is much easier to be treated than silicon nanocrystal grains. The trap concentration is basically high and the film is easier to accumulate a charge in high concentration than when manufacturing silicon nanocrystal grains artificially. Because the film itself can hold a charge, the silicon oxide film (tunnel insulation film) 5 and the interlayer insulation film 7 are reduced in thickness more than when a charge storage region constructed of silicon nanocrystal grains is used for them 5 and 7. The interlayer insulation film 7 can thus be omitted. In this second embodiment, the tunnel insulation film 5 and the interlayer insulation film 7 are formed with a silicon oxide film at a thickness of about 4 nm and at a thickness of about 3 nm, respectively.

### This Embodiment

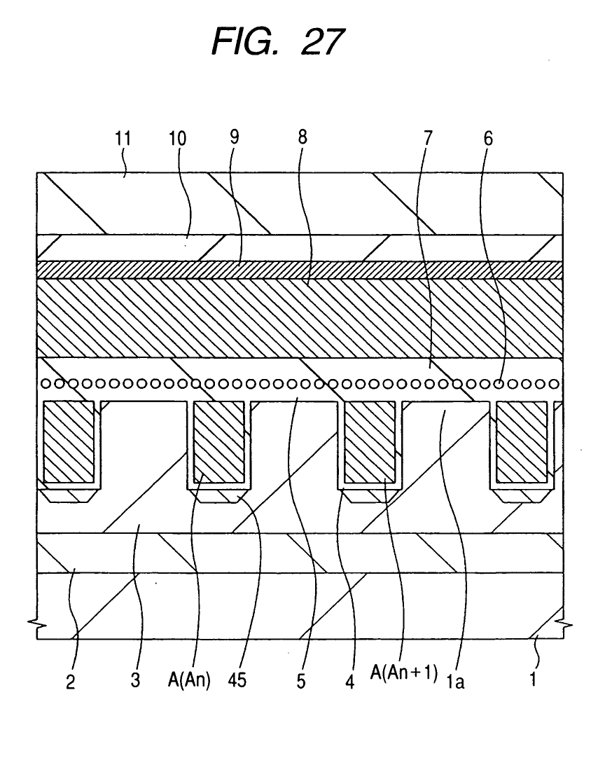

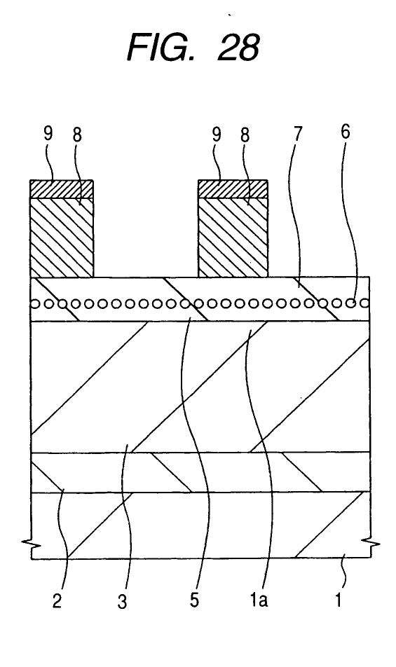

FIG. 27 shows a cross sectional view (cross sectional direction of assist gates) of major portions of a semiconductor substrate of a flash memory in this third embodiment of the present invention. FIG. 28 shows a cross sectional view (cross sectional direction of word lines) of the major portions in a vertical direction.

The memory array configuration and the operation of the flash memory in this third embodiment are the same as those in the first embodiment except that a diffusion layer 45 composed of an n-type impurity is provided just under each assist gate and the space between adjacent word lines is not so narrow as those in the first and second embodiments; minimum-sized lines and spaces are alternated repetitively. In this flash memory, the local data line resistance is lowered more than when the local data lines are constructed of only an inversion layer, respectively. In addition, the characteristic variation among memory mats is thus suppressed. Although the write current is raised/lowered with use of a phenomenon that the resistance of the local data lines D constructed of an inversion layer, respectively is high, the resistance of the local data lines is set low and the potential of the assist gates close to the diffusion layer assumed as sources are set low to raise the resistance of the surface of the substrate 1, which faces a side face of each assist gate A to write information more efficiently. In order to isolate elements of assist gates A from one another, the potential of the assist gates is set low and the side face of each assist gate A is assumed as an isolation region.

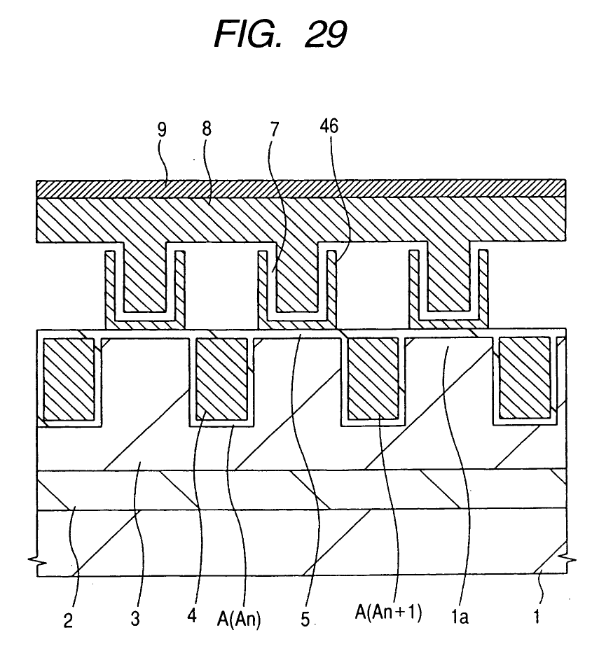

Even in this structure, narrowly spaced word lines may be used just like in the first and second embodiments, so that the area of the memory cells, as well as the manufacturing cost are reduced effectively. An insulation film having a trapping function, such as silicon nitride, alumina, or the like may also be used for each charge accumulating region. In addition, a continuous film of polycrystalline silicon may be used for a floating gate structure just like in ordinary flash memories. FIG. 29 shows an example of such a structure. If an object floating gate 46 is constructed of a continuous film, a larger capacitance can be assumed between each word line and the floating gate 46 by shaping the floating gate properly. As a result, writing/erasing is made faster even at a low voltage.

### Fourth Embodiment

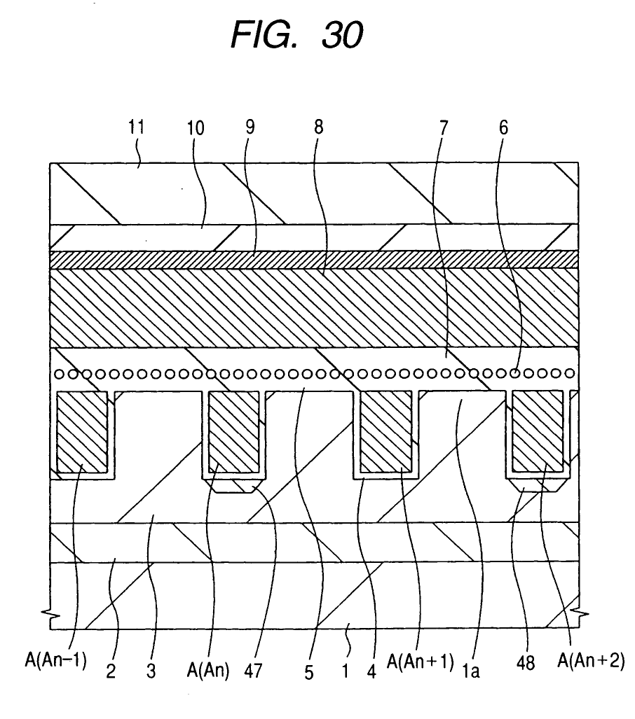

FIG. 30 shows a cross sectional view (cross sectional direction of assist gates) of major portions of a semiconductor substrate of a flash memory in this fourth embodiment.

The flash memory in this fourth embodiment has the same cross sectional structure as that of the flash memory in the above third embodiment. Unlike the third embodiment, however, the flash memory in this fourth embodiment includes diffusion layers 47 and 48 constructed of an n-type impurity just under every other assist gate. Both write and read operations of the flash memory in this fourth embodiment are different from those in the above embodiments, so that the different points of those operations will be described here.

When in writing, adjacent two assist gates (An and An+1, for example) are used as a source and a drain, respectively in the above embodiments. In this fourth embodiment, however, the diffusion layers 47 and 48 provided just under the two assist gates A (An and An+2, for example) at both sides of the next diffusion layer line, that is, (An+1, for example) are used as a source and a drain. Those diffusion layers 47 and 48 are set at 0 V and 4 V, respectively and the assist gate A (An+1) between them is set at 1.5 V. At that time, the assist gate A (An) is set at a voltage higher than that of the diffusion layer 47, for example, set at 3 V while the assist gate A (An+2) is set at a voltage higher than that of the diffusion layer 48, for example, at 7 V. As a result, an inversion layer is formed at the side faces of the assist gates A (An and An+2), respectively. In order to turn off the diffusion layer provided under an assist gate A to which no current is to be flown, the assist gates A (An+1 and An+3) are set at a voltage lower than that of the assist gate A (An+1), for example, at −1 V. If a high voltage is applied to an object word line W, an inversion layer is formed on the silicon substrate surface 1a and a current flows between the diffusion layers 47 and 48. However, the voltage of the assist gate A (An+1) between them is low, the diffusion layers provided just under the assist gate A (An+1) and at the side face thereof are weakly inverted and high in resistance. As a result, strong electric field concentration occurs around the right end of the assist gate A (An+1), thereby the charge holding means between the assist gates A (An+1) and (An+2) is charged. If the voltages are exchanged between the diffusion layers 47 and 48, as well as between the corresponding assist gates A (An) and (An+2), the left side of the assist gate A (An+1) is charged. It is also possible to set the assist gate A (An+1) at a low voltage to isolate elements from one another electrically, thereby charging both sides of the assist gate A (An+1) or (An+3) with use of the assist gate A (An+1) or (An+3) just like (An+1) in the above writing operation. In other words, each portion between given adjacent assist gates A can be charged.

Next, a read operation will be described. It is assumed here that object information to be read is retained in a charge storage region between two assist gates A (An+1) and (An+2). In that case, a predetermined voltage (3 V, for example) is applied to the assist gate A (An+1) to form an inversion layer just under the assist gate A (An+1) and a side face thereof, respectively. The inversion layers are used as inversion layer lines just like in the first embodiment. Those inversion layers are applied 0 V from a terminal provided in the subject memory mat, respectively. Then, the diffusion layer 48 is set at a predetermined voltage, for example, at 1 V. Then, a predetermined read voltage, for example, 4 V is applied to the object word line W, a read current flows between each inversion layer line and the diffusion layer 48. The read current value will differ among retained information items and this phenomenon is used to read the object information. At that time, the potential of the diffusion layer 47 is set equally to that (O V) of the inversion layer, the potential of the assist gate A (An) is set low, for example, at 0 V, or both settings are done to avoid the influence of other retained information items than the object one. Assist gates A are driven four by four repetitively to carry out the above read operation.

The configuration and driving method in this fourth embodiment can be employed to extend the distance between adjacent diffusion layers double those in the third embodiment. Consequently, the leak current from between adjacent diffusion layers is suppressed.

Of course, the narrow pitched word lines may be used just like in the above first to third embodiments to reduce the area of the memory cells and the manufacturing cost effectively. As a charge storage region, an insulation film having a trapping function, such as silicon nitride, alumina, or the like may be used. A continuous polycrystalline silicon film may be used to form the floating gate structure just like ordinary flash memories.

Although the embodiments of the present invention achieved by the present inventor et al. have been described concretely with reference to some embodiments, it is to be understood that modifications will be apparent to those skilled in the art without departing from the spirit of the invention.

The semiconductor device of the present invention can widely be applied to various semiconductor products which require nonvolatile memories.

1. A semiconductor memory device, comprising:
a plurality of gate lines embedded in a first conductive type semiconductor substrate in parallel to one another;
a plurality of word lines practically provided vertically to said plurality of electrode lines; and
charge holding means enclosed by an insulation film between a main surface of said semiconductor substrate and each of said plurality of word lines;
wherein said semiconductor memory device has a memory array structured so that a second conductive type inversion layer formed electrically with said plurality of electrode lines on a surface of said semiconductor substrate and used as lines for the connection between a plurality of memory cells, respectively.

2. The semiconductor memory device according to claim 1,
wherein the space between adjacent those of said plurality of word lines is under ½ of the width of said word line.

3. The semiconductor memory device according to claim 1,
wherein said charge holding means consists of a plurality of semiconductor nanocrystal grains or metallic nanocrystal grains insulated from one another by said insulation film provided therebetween.

4. The semiconductor memory device according to claim 1,
wherein said charge holding means is an insulation film functioning as a charge trap.

5. The semiconductor memory device according to claim 4,
wherein said charge holding means is constructed of silicon nitride or alumina.

6. The semiconductor memory device according to claim 1,
wherein each of said plurality of memory cells is a multibit storage memory cell.

7. A semiconductor memory device, comprising:
a plurality of assist gates embedded in a first conductive type substrate with a first insulation film provided therebetween and extended in a first direction;
a plurality of word lines formed over said plurality of assist gates with a second insulation film provided therebetween and extended in a second direction that crosses said first direction; and
a plurality of memory cells disposed respectively at an intersection of each of said plurality of assist gates and each of said plurality of word lines.

8. The semiconductor memory device according to claim 7,
wherein the space between adjacent those of said plurality of word lines is under ½ of the word of said word line.

9. The semiconductor memory device according to claim 7,
wherein a second conductor type diffusion layer is formed under said plurality of assist gates with said first insulation film provided therebetween.

10. A semiconductor memory device, comprising:
a plurality of assist gates extended in a first direction of a semiconductor substrate;
a plurality of word lines extended in a second direction that crosses said first direction; and
a plurality of memory cells disposed respectively at an intersection of each of said plurality of assist gates and each of said plurality of word lines;
wherein the space between adjacent those of said plurality of word lines is under ½ of the width of said word line and made by a gap.

11-13. (canceled)
